(19) United States
(12) Patent Application Publication
(10) Pub. No.: US 2006/0035412 A1
(43) Pub. Date: Feb. 16, 2006

(54) Semiconductor attachment method

(76) Inventor: Eugen Popescu, Santee, CA (US)

Correspondence Address: PETER F WEINBERG;GIBSON DUNN AND CRUTCHER LLP, SUITE 4100, 1801 CALIFORNIA STREET, DENVER, CO, 80202, US

(21) Appl. No.: 10/918,241

(22) Filed: Aug. 13, 2004

(51) Int. Cl. H01L 21/50; H01L 23/48

(52) U.S. Cl. 438/119; 257/772

(57) ABSTRACT

An improved semiconductor attachment method that works with mixed assemblies on printed circuit boards or ceramic substrates maintains reliability and reduces the amount of lead-based solders used. A soft solder layer, which may be high in lead content, is deposited on the terminations of a semiconductor die. The soft solder layer acts as a cushion, protecting the fragile semiconductor die from thermally induced stress. Conductor pads of the substrate are printed with a low melting point solder paste that is preferably lead-free. The semiconductor die, along with other electric components, are mounted on the proper conductor pads. The low melting point solder paste is reflowed, heating the substrate and the other electric components. As a result, the low melting point solder paste forms strong solid metal solder joints between the conductor pads of the substrate and the terminations of the semiconductor die and the other electric components.

### FIELD OF THE INVENTION

This invention relates to semiconductors, and more particularly, to an attachment method for mixed assemblies of semiconductors and lower temperature rated components on the same substrate.

### BACKGROUND OF THE INVENTION

It was the standard practice for many years in the electronics industry to utilize high melting point solder alloys having a high lead content to solder semiconductors to ceramic substrates. In recent years, however, the industry has shifted towards the use of tin-silver or tin-silver-copper and other “lead-free” solder alloys due to the environmental concerns associated with solder alloys that contain lead. Indeed, in some parts of the world, legislative restrictions on hazardous substances may eventually ban the use of lead-based solders.

In some applications, such as power switching assemblies, testing has shown that long term reliability suffers when common lead-free solders are used for semiconductor die attachment. In the most frequently observed failure mechanism, the semiconductors tend to crack and delaminate from the substrate. This type of failure mechanism is uncommon when lead-bearing solders are used, which is due to the high concentration of soft, malleable lead which dose not transfer excessive stress onto the semiconductors. Thus, cracking and delamination are not a common occurrence when lead-bearing solders are used.

Due to their high melting point, lead-bearing solders are not without their problems in certain applications. A classic example is a mixed assembly of semiconductors and other electronic components that have a lower temperature rating (which are normally soldered with eutectic tin-lead or lead-free solders) that have to be soldered on the same substrate. More challenging applications involve making such attachments to a printed circuit board (“PCB”), which can suffer significant damage upon exposure to the high temperatures necessary for soldering.

Thus, there is a need in the art for an improved semiconductor attachment method that will work with mixed assemblies and with printed circuit boards or ceramic substrates that will maintain reliability and reduce the amount of lead-based solders used.

### BRIEF DESCRIPTION OF THE DRAWINGS

FIG. 1 shows an elevation view of a semiconductor die with soft solder metallization layers on the top and bottom surfaces in an embodiment of the semiconductor attachment method of the present invention.

FIG. 2 shows an elevation view of a printed circuit board or ceramic substrate with lead-free solder paste printed on the conductor pads in an embodiment of the semiconductor attachment method of the present invention.

FIG. 3 shows an elevation view of the printed circuit board or ceramic substrate of FIG. 2 and the semiconductor die of FIG. 1 and other electronic components mounted thereon in an embodiment of the semiconductor attachment method of the present invention.

FIG. 4 shows, an elevation view of the assembly of FIG. 3 after solder reflow, and the resulting solder connections in an embodiment of the semiconductor attachment method of the present invention.

### DETAILED DESCRIPTION OF THE INVENTION

From an ideal manufacturing standpoint, all of the electronic components for a mixed assembly should be attached in one single process step, with only one solder alloy printed across the printed circuit board. There would also be no thermally induced damage to any of the components, and the resulting connections would suffer no loss of reliability. As discussed above, there is no one solder presently available that can accomplish the ideal objective. The lead-based solders produce reliable connections, but the high temperatures required can damage electrical components with low temperature ratings. The lead-free solders have lower temperatures that prevent thermal damage to the sensitive components, but the resulting connections to the substrates suffer in reliability, resulting in shorter life-span of the final product.

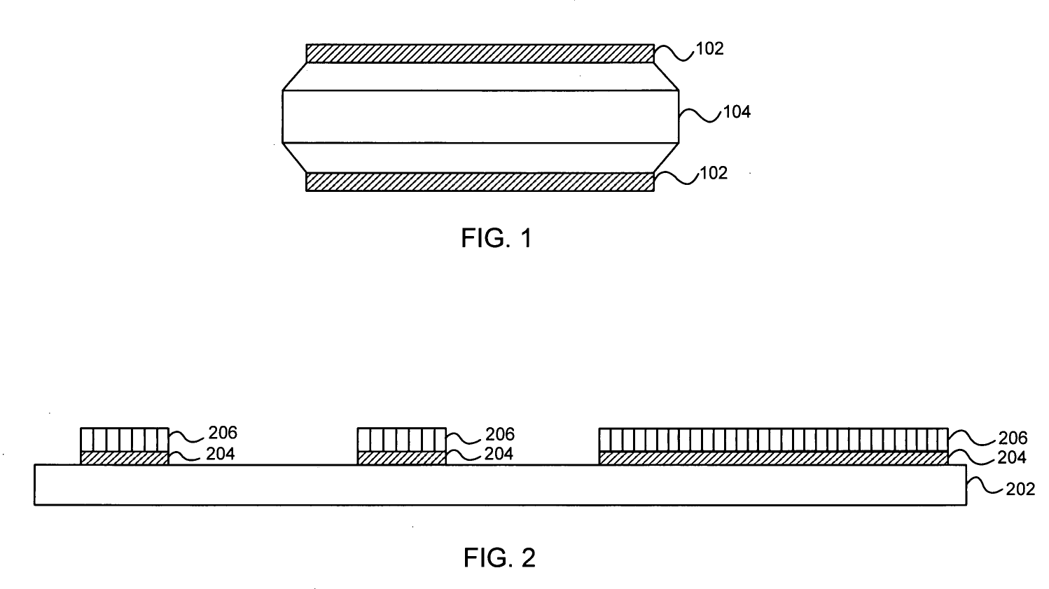

Referring now to the Figures, in which like reference numerals refer to structurally and/or functionally similar elements thereof, FIG. 1 shows an elevation view of a semiconductor die with soft solder metallization layers on the top and bottom surfaces. Referring now to FIG. 1, in the semiconductor attachment method of the present invention for a mixed assembly, in a first step, Soft Solder Layers 102, which are high in lead content, are deposited on the terminations of Semiconductor Die 104. Soft Solder Layer 102 acts as a cushion, protecting the fragile silicon Semiconductor Die 104 from thermally induced stress when current is applied. Soft Solder Layers 102 may have a composition of any of the following solder alloy types: Sn/Pb (Tin/Lead), Sn/Pb/X (where X is Ag (Silver) or In (Indium)), Pb/In (Lead/Indium), and Pb/In/Ag (Lead/Indium/Silver). In all types, the Pb component is 85% or more. Examples of frequently used alloys include Sn 10/Pb 88/AG 2, Sn 10/Pb 90, Sn 5/Pb 95, Sn 3/Pb 97, and Sn 5/Pb 92.5/In 2.5.

In one embodiment of the invention, the depositing step is performed by printing solder paste dots on the terminations of Semiconductor Die 104, and then reflow soldering by bringing the solder paste over its melting temperature by heating Semiconductor Die 104 in a reflow oven, with a hot plate system, or by means of selective soldering. This results in the thin uniform Soft Solder Layers 102 on Semiconductor Die 104.

In another embodiment of the invention, a powder coating technique may be used. The Semiconductor Die 104 is heated to a predetermined temperature followed by dipping Semiconductor Die 104 in solder powder. Particles of solder powder stick to the hot terminations, and a subsequent reflowing will smooth out the imperfections, resulting in Soft Solder Layers 102 on Semiconductor Die 104.

FIG. 2 shows an elevation view of a printed circuit board (“PCB”) or ceramic substrate with lead-free solder paste printed on the conductor pads in an embodiment of the semiconductor attachment method of the present invention. Referring now to FIG. 2, PCB/Ceramic Substrate 202 has Conductor Pads 204, which are used to mount electrical components. In a second step, Low Melting Point Solder Paste 206, which may or may not be lead free, is deposited onto Conductor Pads 204. Depending on each particular application, Low Melting Point Solder Paste 206 may be deposited onto Conductor Pads 204 by printing, deposited manually, or deposited by machine. In a preferred embodiment, lead-free solder paste is used having a composition of any of the following types: Sn/Ag (Tin/Silver) and Sn/Ag/Cu (Tin/Silver/Copper). Common Sn/Ag is the eutectic Sn 96.5/Ag 3.5. SAC 405 (Sn 95.5/Ag 4.0/Cu 0.5) and SAC 305 (Sn 96.5/Ag 3.0/Cu 0.5) are also common.

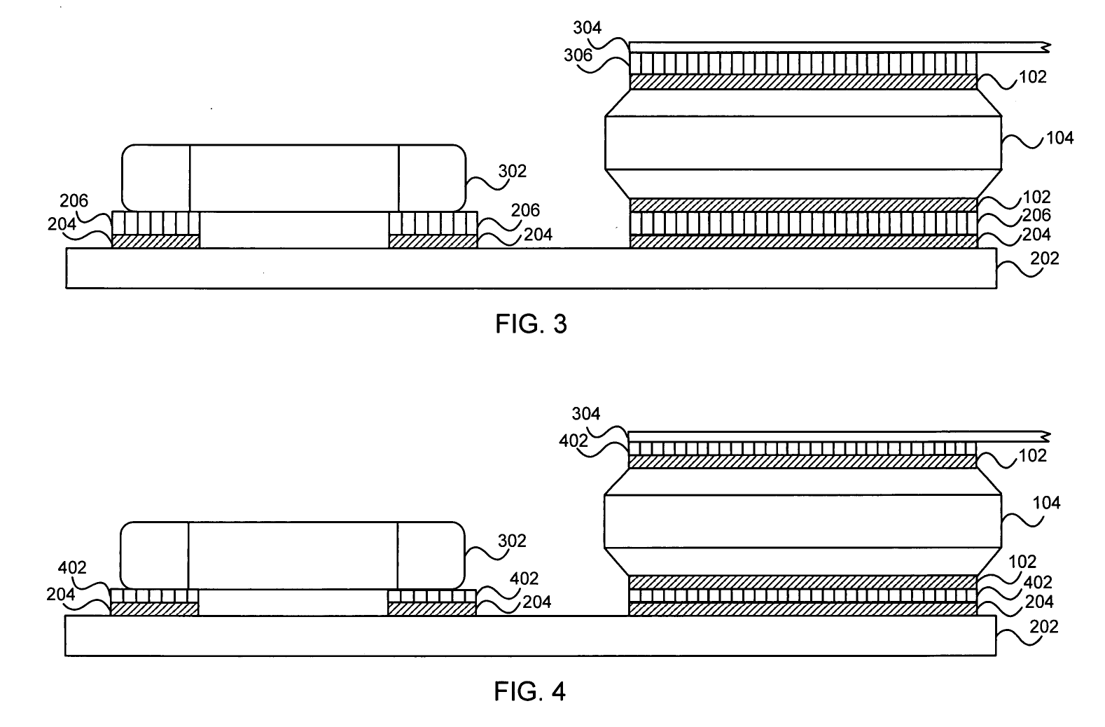

FIG. 3 shows an elevation view of the printed circuit board or ceramic substrate of FIG. 2 and the semiconductor die of FIG. 1 and other electronic components mounted thereon in an embodiment of the semiconductor attachment method of the present invention. Referring now to FIG. 3, in a third step, Semiconductor Die 104 with Soft Solder Layer 102 and the rest of the electric components, represented by Other Components 302, are mounted on the proper Conductor Pads 204 that have been deposited with Low Melting Point Solder Paste 206. Other Components 302 typically have a lower temperature rating than Semiconductor Die 104. Also shown in FIG. 3 is Low Melting Point Solder Paste 306 which is dispensed onto the upper layer of Soft Solder Layer 102 on Semiconductor Die 104. One or more Copper Connectors 304 are then positioned on top of Low Melting Point Solder Paste 306.

FIG. 4 shows an elevation view of the assembly of FIG. 3 after solder reflow, and the resulting solder connections in an embodiment of the semiconductor attachment method of the present invention. Referring now to FIG. 4, the last step consists of reflow soldering, which is accomplished by bringing Low Melting Point Solder Pastes 206 and 306 over their melting temperature by heating PCB/Ceramic Substrate 202, Other Components 302, and Copper Connectors 304 in a reflow oven, with a hot plate system, or by means of selective soldering. As a result, Low Melting Point Solder Pastes 206 and 306 form strong solid metal Solder Joints 402 between Conductor Pads 204 of PCB/Ceramic Substrate 202 and Semiconductor Die 104 and between Semiconductor Die 104 and Copper Connectors 304.

Thermal fatigue resistance testing was performed to verify the performance of the semiconductor attachment method over traditional methodology. Eight 40 amp solid state relay units were tested, referred to as units under test (“UUT”). During assembly, the silicon-controlled rectifiers (“SCRs”) had a layer of soft solder deposited on the existing terminations. The solder used in this test was Sn 10/Pb 88/AG 2. The solder used for assembly, including the semiconductor die attachment, was a common lead-free solder alloy of tin-silver-copper known as SAC 405.

All eight units under test had all outputs connected in series, with no external heat sink attached. An electric current was used to heat up the units to 125° C. and then cooled by forced air with fans down to 40° C. All units were temperature cycled for one to two hours to allow them to stabilize between the high temperature of 125° C. and the low temperature of 40° C. After this stabilization period, the setup was changed from a temperature cycle to a time cycle. One complete time cycle consists of a hot period of time in which the current is turned on, which heats up the units, plus a cold period of time in which the current is turned off and forced air cooling is turned on, where the units cool down. The time cycle was conducted under the following parameters:

| | |
|---|---|
| Hot Period: | 99 seconds |
| Cold Period: | 141 seconds |
| Load Type: | Resistive |
| Load Current: | 28.0 Amperes |
| Failure: | Defined as occurring when the temperature |
| | reaches 150° C. during any cycle. |

Table One below shows the results of the test under the above parameters.

TABLE ONE

| | Lead | Solder Composition | | Total Cycles |
|---|---|---|---|---|
| UUT | Frame | SSA | Ceramic | Before |
| Number | Design | Construction | Base Plate | Failure |
| UUT #1 | Standard | SAC 405 | SAC 405 | — |
| UUT #2 | Standard | SAC 405 | SAC 405 | — |
| UUT #3 | Standard | SAC 405 | SAC 405 | — |
| UUT #4 | Standard | SAC 405 | SAC 405 | — |
| UUT #5 | Standard | SAC 405 | SAC 405 | — |
| UUT #6 | Standard | SAC 405 | SAC 405 | — |
| UUT #7 | Standard | SAC 405 | SAC 405 | — |
| UUT #8 | Standard | SAC 405 | SAC 405 | — |

After 5,786 cycles, which is just over sixteen days, the test was stopped, as this number of cycles was well past the number of cycles under which normal units typically fail by several orders of magnitude. All of the units under test were working perfectly at the time the test was stopped. Upon examining each of the units after the test was stopped, no thermal stress induced cracks in the semiconductor material were detected in any of the units.

Having described the present invention, it will be understood by those skilled in the art that many changes in construction and widely differing embodiments and applications of the invention will suggest themselves without departing from the scope of the present invention.

What is claimed is:

1. A method for semiconductor attachment in an assembly, the method comprising the steps of:
(a) depositing a layer of soft solder on at least one termination located on a first surface of a semiconductor die;
(b) depositing a low melting point solder paste on at least one conductor pad of a substrate;
(c) mounting said semiconductor die with said layer of soft solder on said first surface onto said at least one conductor pad having said low melting point solder paste deposited thereon; and
(d) reflowing said low melting point solder paste, wherein a strong solid metal solder joint is formed between said at least one conductor pad of said substrate and said at least one termination on said first surface of said semiconductor die.

2. A method according to claim 1 wherein said depositing step (a) further comprises:
using a soft solder having a lead content of 85% or more.

3. A method according to claim 1 wherein said depositing step (a) further comprises:
printing at least one solder paste dot on said at least one termination of said semiconductor die; and
reflow soldering said solder paste to form said layer of soft solder.

4. A method according to claim 1 wherein said depositing step (a) further comprises:
heating said semiconductor die to a predetermined temperature;
dipping said semiconductor die in a solder powder, wherein a portion of said solder powder sticks to said at least one termination located on said first surface of said semiconductor die; and
reflowing said portion of said solder powder to form said layer of soft solder on said at least one termination.

5. A method according to claim 1 wherein said depositing step (b) further comprises:
using a lead free low melting point solder paste.

6. A method according to claim 1 wherein said depositing step (b) further comprises:
depositing by printing said low melting point solder paste on said at least one conductor pad of said substrate.

7. A method according to claim 1 wherein said depositing step (b) further comprises:
depositing manually said low melting point solder paste on said at least one conductor pad of said substrate.

8. A method according to claim 1 wherein said depositing step (b) further comprises:
depositing by a machine said low melting point solder paste on said at least one conductor pad of said substrate.

9. A method according to claim 1 wherein said mounting step (c) further comprises the step of:
mounting at least one other electric component having a lower temperature rating than said semiconductor die onto another conductor pad of said substrate having said solder paste deposited thereon.

10. A method according to claim 1 wherein said mounting step (c) further comprises the steps of:
depositing said low melting point solder paste on a second surface of said semiconductor die; and
positioning at least one copper connector onto said low melting point solder paste on said second surface of said semiconductor die.

11. A semiconductor assembly comprising:
a semiconductor die having a first surface with a layer of soft solder deposited on at least one termination thereon; and
a substrate having a low melting point solder paste deposited on at least one conductor pad thereon;
wherein said semiconductor die with said layer of soft solder deposited on said first surface is mounted onto said at least one conductor pad having said low melting point solder paste deposited thereon, and further wherein, upon reflowing said low melting point solder paste, a strong solid metal solder joint is formed between said at least one conductor pad of said substrate and said at least one termination on said first surface of said semiconductor die.

12. The semiconductor assembly according to claim 11 wherein said soft solder has a lead content of 85% or more.

13. The semiconductor assembly according to claim 12 wherein said soft solder is a composition selected from the group consisting of Sn/Pb, Sn/Pb/X (where X is Ag or In), Pb/In, and Pb/In/Ag.

14. The semiconductor assembly according to claim 13 wherein said soft solder is at least a one of Sn 10/Pb 88/AG 2, Sn 10/Pb 90, Sn 5/Pb 95, Sn 3/Pb 97, and Sn 5/Pb 92.5/In 2.5.

15. The semiconductor assembly according to claim 11 wherein said low melting point solder paste is lead free.

16. The semiconductor assembly according to claim 15 wherein said low melting point solder paste is a composition selected from the group consisting of Sn/Ag and Sn/Ag/Cu.

17. The semiconductor assembly according to claim 16 wherein said low melting point solder paste is at least a one of Sn 96.5/Ag 3.5, Sn 95.5/Ag 4.0/Cu 0.5, and Sn 96.5/Ag 3.0/Cu 0.5.

18. The semiconductor assembly according to claim 11 wherein said substrate is at least a one of a printed circuit board and a ceramic substrate.

19. The semiconductor assembly according to claim 11 further comprising:
at least one other electric component having a lower temperature rating than said semiconductor die, wherein said at least one other electric component is mounted onto another conductor pad of said substrate having said low melting point solder paste deposited thereon.

20. The semiconductor assembly according to claim 11 further comprising:
a second surface of said semiconductor die located opposite said first surface, said second surface having said low melting point solder paste deposited thereon; and
at least one copper connector positioned onto said low melting point solder paste on said second surface of said semiconductor die.
